(19) United States
(12) Patent Application Publication
(10) Pub. No.: US 2025/0324859 A1
(43) Pub. Date: Oct. 16, 2025

(54) DISPLAY DEVICE AND MANUFACTURING METHOD OF DISPLAY DEVICE

(71) Applicant: Japan Display Inc., Tokyo (JP)

(72) Inventors: Takahiro USHIKUBO, Tokyo (JP); Hiroyuki KIMURA, Tokyo (JP)

(73) Assignee: Japan Display Inc., Tokyo (JP)

(21) Appl. No.: 19/093,314

(22) Filed: Mar. 28, 2025

(30) Foreign Application Priority Data
Apr. 16, 2024 (JP) 2024-065970

(51) Int. Cl. H10K 59/122; H10K 59/12

(52) U.S. Cl. CPC H10K 59/122; H10K 59/1201

(57) ABSTRACT

According to one embodiment, a display device includes a first insulating layer, a first lower electrode located on the first insulating layer and having a first peripheral portion, a second insulating layer located on the first insulating layer, a second lower electrode located on the second insulating layer and having a second peripheral portion, a third insulating layer located on the second insulating layer, a third lower electrode located on the third insulating layer and having a third peripheral portion, and a rib layer overlapping the first peripheral portion, the second peripheral portion, and the third peripheral portion and formed of inorganic material.

### CROSS-REFERENCE TO RELATED APPLICATION

This application is based upon and claims the benefit of priority from Japanese Patent Application No. 2024-065970, filed Apr. 16, 2024, the entire contents of which are incorporated herein by reference.

### FIELD

Embodiments described herein relate generally to a display device and a manufacturing method of a display device.

### BACKGROUND

Recently, display devices with organic light-emitting diodes (OLED) applied thereto as display elements have been put into practical use. This display element comprises a lower electrode, an organic layer covering the lower electrode, and an upper electrode covering the organic layer. The organic layer emit light based on potential differences between the lower electrode and the upper electrode.

An interval between the lower electrodes of adjacent display elements needs to be narrowed to achieve a display device with a high aperture ratio. However, sufficiently narrowing the interval between the lower electrodes is difficult because of the restrictions of processing technique and the like.

### BRIEF DESCRIPTION OF THE DRAWINGS

FIG. 1 is a view showing a configuration example of a display device of the first embodiment.

FIG. 2 is a schematic plan view showing an example of layouts of subpixels.

FIG. 3 is a schematic cross-sectional view of the display device along III-III line in FIG. 2.

FIG. 4 is a view showing an example of layer structures applicable to display elements.

FIG. 5 is a schematic cross-sectional view of the display device along V-V line in FIG. 2.

FIG. 6 is a schematic cross-sectional view of the display device along VI-VI line in FIG. 2.

FIG. 7 is a schematic cross-sectional view of the display device along VII-VII line in FIG. 2.

FIG. 8 is a schematic cross-sectional view showing part of a manufacturing method of the display device of the first embodiment.

FIG. 9 is a schematic cross-sectional view showing a manufacturing process following the process shown in FIG. 8.

FIG. 10 is a schematic cross-sectional view showing a manufacturing process following the process shown in FIG. 9.

FIG. 11 is a schematic cross-sectional view showing a manufacturing process following the process shown in FIG. 10.

FIG. 12 is a schematic cross-sectional view showing a manufacturing process following the process shown in FIG. 11.

FIG. 13 is a schematic cross-sectional view showing a manufacturing process following the process shown in FIG. 12.

FIG. 14 is a schematic cross-sectional view showing a manufacturing process following the process shown in FIG. 13.

FIG. 15 is a schematic cross-sectional view showing a manufacturing process following the process shown in FIG. 14.

FIG. 16 is a schematic cross-sectional view showing a manufacturing process following the process shown in FIG. 15.

FIG. 17 is a schematic cross-sectional view showing a manufacturing process following the process shown in FIG. 16.

FIG. 18 is a schematic cross-sectional view showing a manufacturing process following the process shown in FIG. 17.

FIG. 19 is a schematic cross-sectional view showing a manufacturing process following the process shown in FIG. 18.

FIG. 20 is a schematic cross-sectional view showing a manufacturing process following the process shown in FIG. 19.

FIG. 21 is a schematic cross-sectional view showing a manufacturing process following the process shown in FIG. 20.

FIG. 22 is a schematic cross-sectional view showing a manufacturing process following the process shown in FIG. 21.

FIG. 23 is a schematic cross-sectional view showing a manufacturing process following the process shown in FIG. 22.

FIG. 24 is a schematic cross-sectional view showing a manufacturing process following the process shown in FIG. 23.

FIG. 25 is a schematic cross-sectional view showing a manufacturing process following the process shown in FIG. 24.

FIG. 26 is a schematic cross-sectional view showing a manufacturing process following the process shown in FIG. 25.

FIG. 27 is a schematic cross-sectional view showing a manufacturing process following the process shown in FIG. 26.

FIG. 28 is a schematic cross-sectional view showing a manufacturing process following the process shown in FIG. 27.

FIG. 29 is a schematic cross-sectional view showing a manufacturing process following the process shown in FIG. 28.

FIG. 30 is a schematic cross-sectional view showing a manufacturing process following the process shown in FIG. 29.

FIG. 31 is a schematic cross-sectional view of a display device of the second embodiment.

FIG. 32 is a schematic cross-sectional view of a display device of the third embodiment.

FIG. 33 is a schematic cross-sectional view showing part of a manufacturing method of the display device of the third embodiment.

FIG. 34 is a schematic cross-sectional view showing a manufacturing process following the process shown in FIG. 33.

FIG. 35 is a schematic cross-sectional view showing a manufacturing process following the process shown in FIG. 34.

FIG. 36 is a schematic cross-sectional view of a display device of the fourth embodiment.

FIG. 37 is a view showing an example of structures applicable to display elements of the fourth embodiment.

FIG. 38 is a schematic cross-sectional view of a display device of the fifth embodiment.

FIG. 39 is a schematic cross-sectional view showing part of a manufacturing method of the display device of the fifth embodiment.

### DETAILED DESCRIPTION

In general, according to one embodiment, a display device includes: a first insulating layer; a first lower electrode located on the first insulating layer and having a first peripheral portion; a second insulating layer located on the first insulating layer; a second lower electrode located on the second insulating layer and having a second peripheral portion; a third insulating layer located on the second insulating layer; a third lower electrode located on the third insulating layer and having a third peripheral portion; a rib layer overlapping the first peripheral portion, the second peripheral portion, and the third peripheral portion and formed of inorganic material; a first organic layer located on the first lower electrode; a second organic layer located on the second lower electrode; a third organic layer located on the third lower electrode; a first upper electrode located on the first organic layer; a second upper electrode located on the second organic layer; and a third upper electrode located on the third organic layer.

In general, according to one embodiment, a manufacturing method of a display device includes: forming a first insulating layer; forming a first lower electrode on the first insulating layer; forming a second insulating layer on the first insulating layer; forming a second lower electrode on the second insulating layer; forming a third insulating layer on the second insulating layer; forming a third lower electrode on the third insulating layer; forming a rib layer overlapping a first peripheral portion of the first lower electrode, a second peripheral portion of the second lower electrode, and a third peripheral portion of the third lower electrode; and forming a first organic layer and a first upper electrode that overlap the first lower electrode, a second organic layer and a second upper electrode that overlap the second lower electrode, and a third organic layer and a third upper electrode that overlap the third lower electrode.

The embodiments can provide a display device with high aperture ratio and a manufacturing method of a display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X axis, a Y axis, and a Z axis orthogonal to each other are described to facilitate understanding as needed. A direction parallel to the X axis is referred to as an X direction. A direction parallel to the Y axis is referred to as a Y direction. A direction parallel to the Z axis is referred to as a Z direction. When various elements are viewed parallel to the Z direction, the appearance is defined as a plan view.

The display device of each embodiment is an

organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

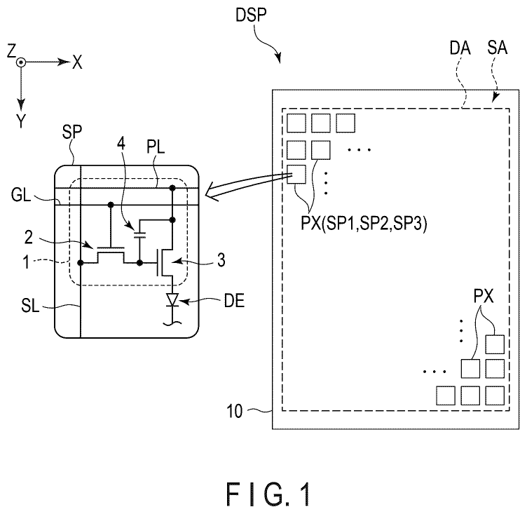

FIG. 1 is a view showing a configuration example of a display device DSP of the first embodiment. The display device DSP comprises an insulating substrate 10. The substrate 10 has a display area DA which displays an image and a surrounding area SA around the display area DA. The substrate 10 may be glass or a resinous film having flexibility.

In the present embodiment, the substrate 10 is rectangular as seen in plan view. The shape of the substrate 10 in plan view is not limited to a rectangle and may be another shape such as a square, a circle or an oval.

The display area DA comprises a plurality of pixels PX arranged in a matrix in the X direction and the Y direction. Each pixel PX includes a plurality of subpixels SP which display different colors. The present embodiment assumes a case where each pixel PX includes a red subpixel SP1, a green subpixel SP2, and a blue subpixel SP3. However, each pixel PX may include a subpixel SP which exhibits another color such as white in addition to the subpixels SP1, SP2, and SP3 or instead of one of the subpixels SP1, SP2, and SP3.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL supplying the pixel circuit 1 of each subpixel SP with scanning signals, a plurality of signal lines SL supplying the pixel circuit 1 of each subpixel SP with video signals, and a plurality of power lines PL are provided in the display area DA. In the example of FIG. 1, the scanning lines GL and the power lines PL extend in the X direction, and the signal lines SL extend in the Y direction.

A gate electrode of the pixel switch 2 is connected to the scanning line GL. A source electrode of the pixel switch 2 is connected to the signal line SL. A drain electrode of the pixel switch 2 is connected to a gate electrode of the drive transistor 3 and the capacitor 4. A source electrode of the drive transistor 3 is connected to the power line PL and the capacitor 4. The drain electrode of the drive transistor 3 is connected to the display element DE.

The configuration of the pixel circuit 1 is not limited to the example of the figure. For example, the pixel circuit 1 may comprise more thin-film transistors and capacitors.

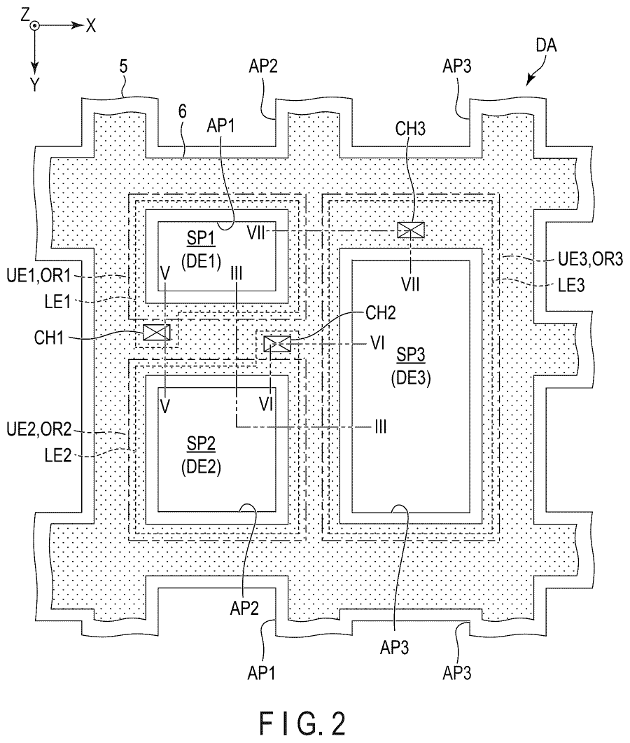

FIG. 2 is a schematic plan view showing an example of layouts of the subpixels SP1, SP2, and SP3. In the example shown in FIG. 2, the subpixels SP1 and SP2 are arranged with the subpixel SP3 in the X direction. Further, the subpixels SP1 and SP2 are arranged in the Y direction.

When the subpixels SP1, SP2, and SP3 are arranged in this layout, in the display area DA, a column in which the subpixels SP1 and SP2 are alternately arranged in the Y direction and a column in which the plurality of subpixels SP3 are repeatedly arranged in the Y direction are formed. These columns are alternately arranged in the X direction. The layout of the subpixels SP1, SP2, and SP3 is not limited to the example of FIG. 2.

A rib layer 5 is provided in the display area DA. The rib layer 5 includes pixel apertures AP1, AP2, and AP3 in the subpixels SP1, SP2, and SP3, respectively. In the example of FIG. 2, the pixel aperture AP3 is greater than the pixel aperture AP2, and the pixel aperture AP2 is greater than the pixel aperture AP1. Thus, among the subpixels SP1, SP2, and SP3, the aperture ratio of the subpixel SP3 is the greatest, and the aperture ratio of the subpixel SP1 is the least. The size of each of the pixel apertures AP1, AP2, and AP3 is not limited to this example. For example, the pixel apertures AP1 and AP2 may have the same size.

The subpixel SP1 comprises a lower electrode LE1 (the first lower electrode), an upper electrode UE1 (the first upper electrode), and an organic layer OR1 (the first organic layer) that overlap the pixel aperture AP1. The subpixel SP2 comprises a lower electrode LE2 (the second lower electrode), an upper electrode UE2 (the second upper electrode), and an organic layer OR2 (the second organic layer) that overlap the pixel aperture AP2. The subpixel SP3 comprises a lower electrode LE3 (the third lower electrode), an upper electrode UE3 (the third upper electrode), and an organic layer OR3 (the third organic layer) that overlap the pixel aperture AP3.

Of the lower electrode LE1, the upper electrode UE1, and the organic layer OR1, parts that overlap the pixel aperture AP1 constitute a display element DE1 of the subpixel SP1. Of the lower electrode LE2, the upper electrode UE2, and the organic layer OR2, parts that overlap the pixel aperture AP2 constitute a display element DE2 of the subpixel SP2. Of the lower electrode LE3, the upper electrode UE3, and the organic layer OR3, parts that overlap the pixel aperture AP3 constitute a display element DE3 of the subpixel SP3. Each of the display elements DE1, DE2, and DE3 may further include a cap layer to be described later. The rib layer 5 surrounds each of the display elements DE1, DE2, and DE3.

The pixel circuits 1 (shown in FIG. 1) of the subpixels SP1, SP2, and SP3 are provided below the respective lower electrodes LE1, LE2, and LE3. The lower electrode LE1 is connected to the pixel circuit 1 of the subpixel SP1 through a contact hole CH1. The lower electrode LE2 is connected to the pixel circuit 1 of the subpixel SP2 through a contact hole CH2. The lower electrode LE3 is connected to the pixel circuit 1 of the subpixel SP3 through a contact hole CH3.

A partition 6 is provided in the display area DA. The partition 6 is located above the rib layer 5 to entirely overlap the rib layer 5. In the example of FIG. 2, the partition 6 has a plan shape similar to that of the rib layer 5. In other words, the partition 6 includes an aperture in each of the subpixels SP1, SP2, and SP3. From another viewpoint, each of the rib layer 5 and the partition 6 has a grating shape as seen in plan view and surrounds each of the display elements DE1, DE2, and DE3. More specifically, the rib layer 5 and the partition 6 surrounds each of the lower electrodes LE1, LE2, and LE3, the organic layers OR1, OR2, and OR3, and the upper electrodes UE1, UE2, and UE3. The partition 6 functions as lines which apply a common voltage to the upper electrodes UE1, UE2, and UE3.

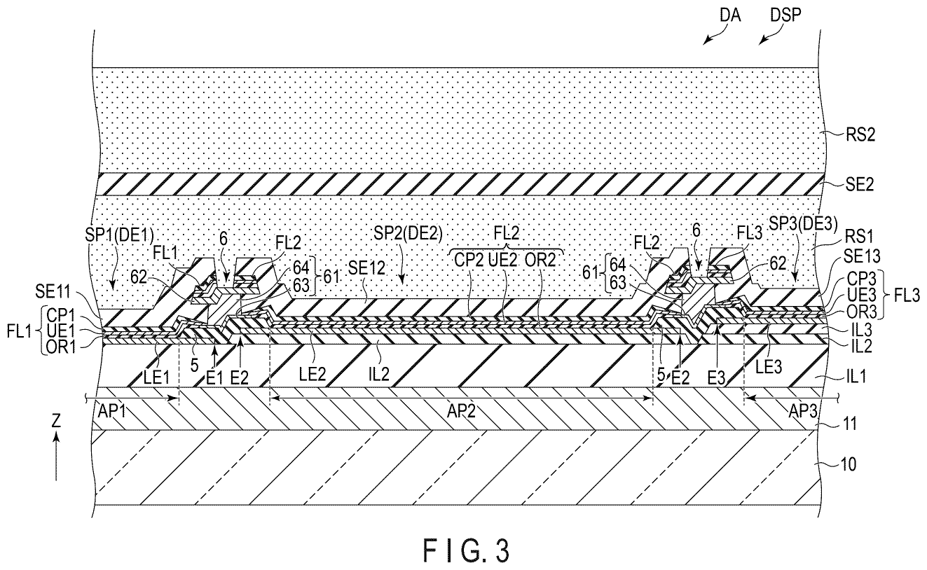

FIG. 3 is a schematic cross-sectional view of the display device DSP along III-III line in FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1.

The display device DSP comprises insulating layers IL1, IL2, and IL3. The circuit layer 11 is covered with the insulating layer IL1 (the first insulating layer). The insulating layer IL1 functions as a planarization film which planarizes irregularities formed by the circuit layer 11. The lower electrode LE1 and the insulating layer IL2 (the second insulating layer) are located on the insulating layer IL1. In the example shown in FIG. 3, the lower electrode LE1 and the insulating layer IL2 are spaced apart from each other. The lower electrode LE2 and the insulating layer IL3 (the third insulating layer) are located on the insulating layer IL2. In the example shown in FIG. 3, the lower electrode LE2 and the insulating layer IL3 are spaced apart from each other. The lower electrode LE3 is located on the insulating layer IL3.

The lower electrode LE1 has a peripheral portion E1 (the first peripheral portion), the lower electrode LE2 has a peripheral portion E2 (the second peripheral portion), and the lower electrode LE3 has a peripheral portion E3 (the third peripheral portion). The peripheral portion E1 overlaps the insulating layer IL1 in the Z direction. The peripheral portion E2 overlaps the insulating layers IL1 and IL2 in the Z direction. The peripheral portion E3 overlaps the insulating layers IL1, IL2, and IL3 in the Z direction.

The rib layer 5 overlaps the peripheral portions E1, E2, and E3. In the example shown in FIG. 3, the rib layer 5 directly covers the peripheral portions E1, E2, and E3. Further, the rib layer 5 covers end portions of the insulating layers IL2 and IL3. The rib layer 5 contacts the insulating layer IL1 between the lower electrode LE1 and the lower electrode LE2 and between the lower electrode LE2 and the lower electrode LE3.

The partition 6 includes a conductive lower portion 61 provided on the rib layer 5 and an upper portion 62 provided on the lower portion 61. The upper portion 62 has the width greater than that of the lower portion 61. This configuration allows the both end portions of the upper portion 62 to protrude relative to the side surfaces of the lower portion 61. This shape of the partition 6 is called an overhang shape. The peripheral portions E1, E2, and E3 are located directly under the partition 6.

In the example of FIG. 3, the lower portion 61 includes a bottom layer 63 and a stem layer 64. The bottom layer 63 is located on the rib layer 5 and formed to be thinner than the stem layer 64. The stem layer 64 is located on the bottom layer 63. In the example of FIG. 3, the both end portions of the bottom layer 63 protrude relative to the side surfaces of the stem layer 64. Further, the both end portions of the bottom layer 63 are located between the end portion of the upper portion 62 and the side surface of the stem layer 64 in plan view. The upper portion 62 is provided on the stem layer 64.

The organic layer OR1 is located on the lower electrode LE1. The upper electrode UE1 is located on the organic layer OR1. The organic layer OR1 covers the lower electrode LE1 through the pixel aperture AP1. The upper electrode UE covers the organic layer OR1 and faces the lower electrode LE1.

The organic layer OR2 is located on the lower electrode LE2. The upper electrode UE2 is located on the organic layer OR2. The organic layer OR2 covers the lower electrode LE2 through the pixel aperture AP2. The upper electrode UE2 covers the organic layer OR2 and faces the lower electrode LE2.

The organic layer OR3 is located on the lower electrode LE3. The upper electrode UE3 is located on the organic layer OR3. The organic layer OR3 covers the lower electrode LE3 through the pixel aperture AP3. The upper electrode UE3 covers the organic layer OR3 and faces the lower electrode LE3. In the example shown in FIG. 3, the organic layers OR1, OR2, and OR3 are configured to emit light in colors different from one another. The upper electrodes UE1, UE2, and UE3 contact the side surface of the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers that improve the extraction efficiency of light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

A part of the stacked film FL1 is located on the upper portion 62. This part is spaced apart from a part that is located around the partition 6 of the stacked film FL1 (in other words, from the part that constitutes the display element DE1). Similarly, a part of the stacked film FL2 is located on the upper portion 62. This part is spaced apart from a part that is located around the partition 6 of the stacked film FL2 (in other words, from the part that constitutes the display element DE2). Similarly, a part of the stacked film FL3 is located on the upper portion 62. This part is spaced apart from a part that is located around the partition 6 of the stacked film FL3 (in other words, from the part that constitutes the display element DE3).

Sealing layers SE11, SE12, and SE13, which respectively cover the stacked films FL1, FL2, and FL3, are respectively provided in the subpixels SP1, SP2, and SP3. More specifically, the sealing layer SE11 continuously covers the cap layer CP1 and the partition 6 around the subpixel SP1. The sealing layer SE12 continuously covers the cap layer CP2 and the partition 6 around the subpixel SP2. The sealing layer SE13 continuously covers the cap layer CP3 and the partition 6 around the subpixel SP3.

In the example of FIG. 3, the stacked film FL1 and the sealing layer SE11 located on the partition 6 between the subpixels SP1 and SP2 are spaced apart from the stacked film FL2 and the sealing layer SE12 located on this partition 6. The stacked film FL1 and the sealing layer SE11 located on the partition 6 between the subpixels SP1 and SP3 are spaced apart from the stacked film FL3 and the sealing layer SE13 located on this partition 6.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

A cover member such as a polarizer, a protective film, and a cover glass may be further provided above the resin layer RS2. This cover member may be attached to the resin layer RS2 via, for example, an adhesive layer such as an optical clear adhesive (OCA).

The insulating layer IL1 is formed of an organic insulating material such as polyimide. Each of the insulating layers IL2 and IL3, the rib layer 5, and the sealing layers SE11, SE12, SE13, and SE2 is formed of an inorganic insulating material such as a silicon nitride (SiNx), a silicon oxide (SiOx), or a silicon oxynitride (SiON). For example, each of the insulating layers IL2 and IL3 and the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating material) such as an epoxy resin or an acrylic resin.

Each of the lower electrodes LE1, LE2, and LE3 has a reflective layer and a pair of conductive oxide layers covering the upper and lower surfaces of the reflective layer. The reflective layer is formed of, for example, a metallic material having excellent light-reflecting properties, such as silver. Each of the conductive oxide layers can be formed of, for example transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

For example, each of the bottom layer 63 and the stem layer 64 of the partition 6 is formed of a metal material. For the metal material of the bottom layer 63, for example, molybdenum (Mo), titanium (Ti), titanium nitride (TiN), a molybdenum-tungsten alloy (MoW), or a molybdenum-niobium alloy (MoNb) can be used. For the metal material of the stem layer 64, for example, aluminum (Al), an aluminum-neodymium alloy (AlNd), an aluminum-yttrium alloy (AlY), or an aluminum-silicon alloy (AlSi) can be used. For example, at least one of the bottom layer 63 and the stem layer 64 may comprise a stacked layer structure in which a plurality of layers are stacked. The stem layer 64 may include a layer formed of an insulating material.

For example, the upper portion 62 of the partition 6 includes a stacked layer structure comprising a lower layer formed of a metal material and an upper layer formed of a conductive oxide. For the metal material forming the lower layer, for example, titanium, a titanium nitride, molybdenum, tungsten, a molybdenum-tungsten alloy, or a molybdenum-niobium alloy can be used. For the conductive oxide forming the upper layer, for example, ITO or IZO may be used. The upper portion 62 may comprise a single-layer structure of a metal material. The upper portion 62 may further include a layer formed of an insulating material.

Common voltage is applied to the partition 6. This common voltage is applied to each of the upper electrodes UE1, UE2, and UE3 in contact with the side surfaces of the lower portion 61. Pixel voltages according to the video signals of the signal lines SL are applied to the lower electrodes LE1, LE2, and LE3 through the respective pixel circuits 1 provided in the subpixels SP1, SP2, and SP3.

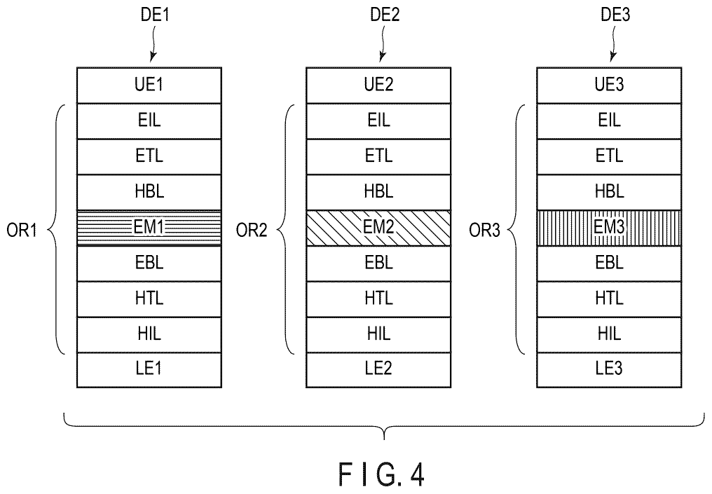

FIG. 4 is a view showing examples of layer structures applicable to the display elements DE1, DE2, and DE3. For example, the following assumes a case where the lower electrodes LE1, LE2, and LE3 correspond to anodes, and the upper electrodes UE1, UE2, and UE3 correspond to cathodes.

The organic layer OR1 comprises a hole injection layer HIL, a hole transport layer HTL, an electron blocking layer EBL, a light emitting layer EM1, a hole blocking layer HBL, an electron transport layer ETL, and an electron injection layer EIL. The hole injection layer HIL is located on the lower electrode LE1. The hole transport layer HTL is located on the hole injection layer HIL. The electron blocking layer EBL is located on the hole transport layer HTL. The light emitting layer EM1 is located on the electron blocking layer EBL. The hole blocking layer HBL is located on the light emitting layer EM1. The electron transport layer ETL is located on the hole blocking layer HBL. The electron injection layer EIL is located on the electron transport layer ETL. The upper electrode UE1 is located on the electron injection layer EIL. The light emitting layer EM1 is formed of a material that emits light in the red wavelength range.

If necessary, the organic layer OR1 may include other function layers, such as a carrier generation layer in addition to the above function layers. Alternatively, the organic layer OR1 may exclude at least one of the above function layers.

In the display element DE2, the organic layer OR2 between the lower electrode LE2 and the upper electrode UE2 comprises a light emitting layer EM2 instead of the light emitting layer EM1. Except this point, the display element DE2 and the display element DE1 have the same configuration. In the display element DE3, the organic layer OR3 between the lower electrode LE3 and an upper electrode UE3 comprises a light emitting layer EM3 instead of the light emitting layer EM1. Except this point, the display element DE3 and the display element DE1 have the same configuration. The light emitting layer EM2 is formed of a material that emits light in the green wavelength range. The light emitting layer EM3 is formed of a material that emits light in a blue wavelength range.

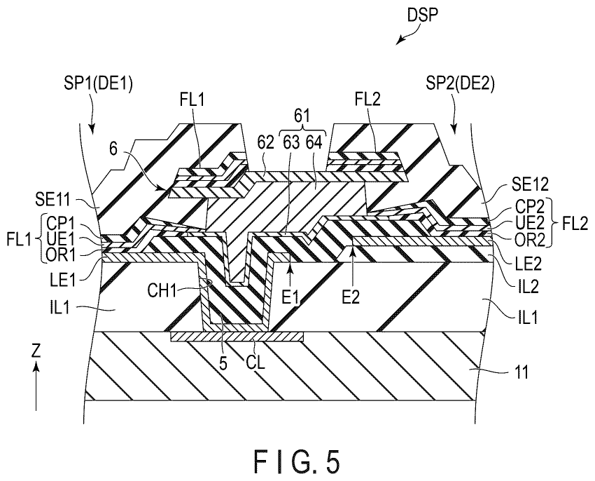

FIG. 5 is a schematic cross-sectional view of the display device DSP along V-V line in FIG. 2. FIG. 5 to FIG. 7 omit the illustration of the substrate 10, the resin layers RS1 and RS2, and the sealing layer SE2 shown in FIG. 3.

The insulating layer IL1 has a contact hole CH1 (the first contact hole) overlapping the lower electrode LE1 in the Z direction. The contact hole CH1 penetrates the insulating layer IL1. The lower electrode LE1 contacts a conductive layer CL included in the circuit layer 11 through the contact hole CH1. The conductive layer CL corresponds to the source electrode or the drain electrode of the drive transistor 3 shown in FIG. 1.

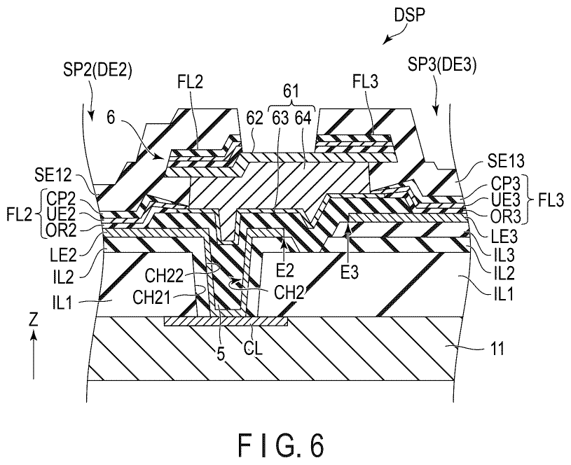

FIG. 6 is a schematic cross-sectional view of the display device DSP along VI-VI line in FIG. 2. The insulating layer IL1 has a contact hole CH21 (the second contact hole) overlapping the lower electrode LE2 in the Z direction. The contact hole CH21 penetrates the insulating layer IL1. The insulating layer IL2 has a contact hole CH22 (the fourth contact hole) overlapping a contact hole CH11 in the Z direction. The contact hole CH22 penetrates the insulating layer IL2. A contact hole CH2 is constituted by the contact holes CH21 and CH22. The lower electrode LE2 contacts the conductive layer CL through the contact hole CH2.

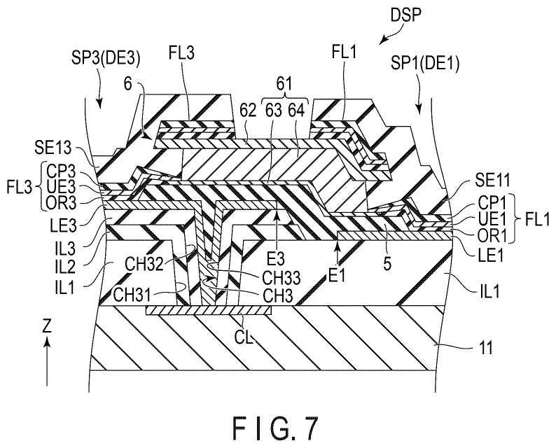

FIG. 7 is a schematic cross-sectional view of the display device DSP along VII-VII line in FIG. 2. The insulating layer IL1 has a contact hole CH31 (the third contact hole) overlapping the lower electrode LE3 in the Z direction. The contact hole CH31 penetrates the insulating layer IL1. The insulating layer IL2 has a contact hole CH32 (the fifth contact hole) overlapping the contact hole CH31 in the Z direction. The contact hole CH32 penetrates the insulating layer IL2. The insulating layer IL3 has a contact hole CH33 (the sixth contact hole) overlapping the contact holes CH31 and CH32 in the Z direction. The contact hole CH33 penetrates the insulating layer IL3. A contact hole CH3 is constituted by the contact holes CH31, CH32, and CH33. The lower electrode LE3 contacts the conductive layer CL through the contact hole CH3.

An example of a manufacturing method of the display device DSP will be described next.

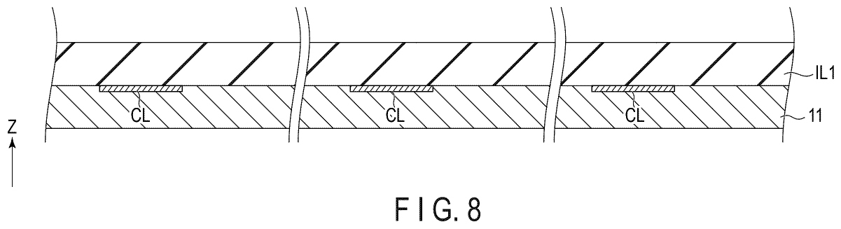

FIG. 8 to FIG. 30 are schematic cross-sectional views showing part of the manufacturing method of the display device DSP of the first embodiment. These figures omit the illustration of the substrate 10 shown in FIG. 3.

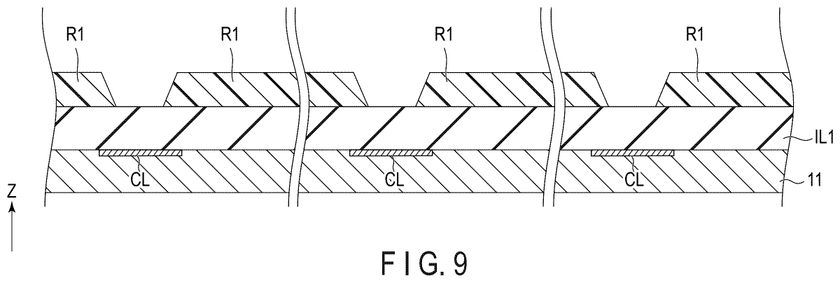

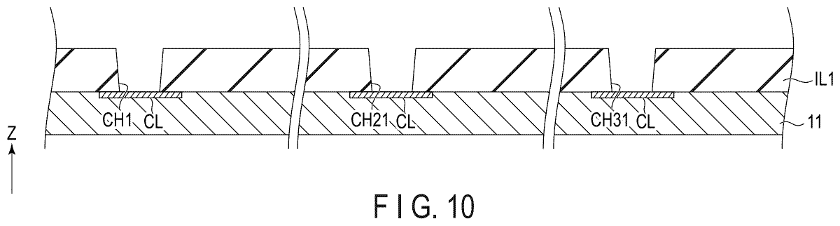

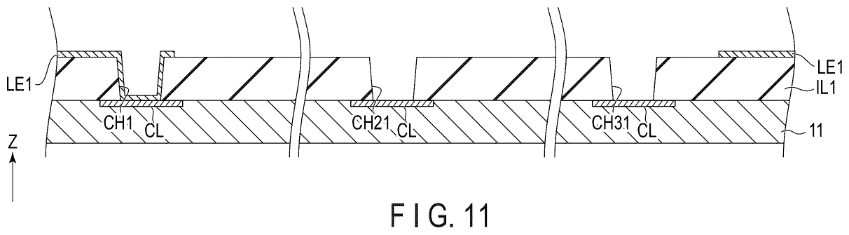

After forming the circuit layer 11 including the conductive layer CL on the substrate 10, the insulating layer IL1 is formed on the conductive layer 11 as shown in FIG. 8. Thereafter, a resist R1 is provided on the insulating layer IL1, as shown in FIG. 9. The resist R1 covers a part of the insulating layer IL1. Thereafter, a part that is exposed from the resist R1 of the insulating layer IL1 is removed by etching using the resist R1 as a mask. This forms the contact holes CH1, CH21, and CH31 in the insulating layer IL1, as shown in FIG. 10. Thereafter, the lower electrode LE1 overlapping the contact hole CH1 is formed, as shown in FIG. 11. The lower electrode LE1 contacts the conductive layer CL through the contact hole CH1.

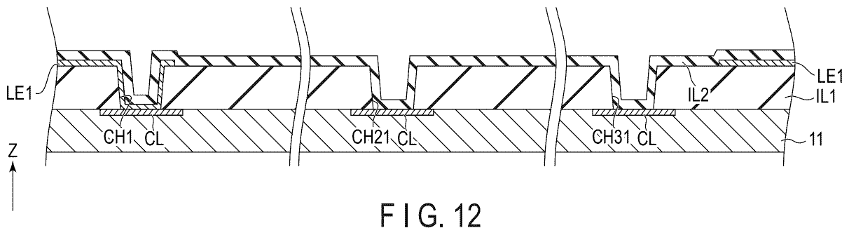

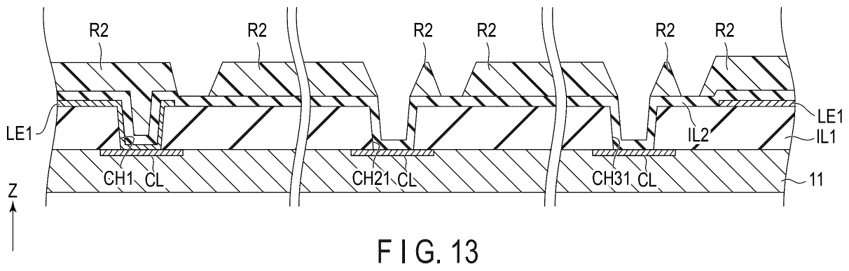

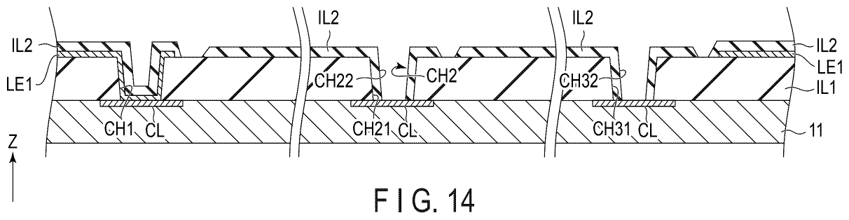

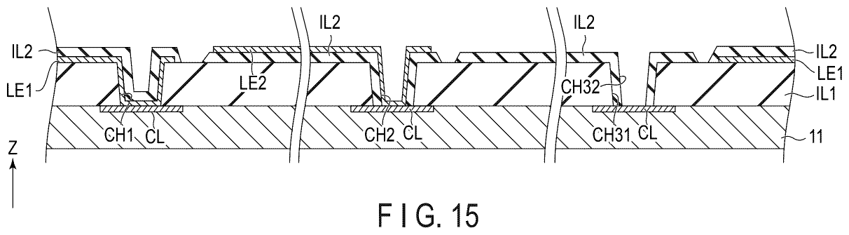

Thereafter, the insulating layer IL2 is formed on the insulating layer IL1 and the lower electrode LE1, as shown in FIG. 12. Thereafter, the resist R2 is provided on the insulating layer IL2, as shown in FIG. 13. A resist R2 covers a part of the insulating layer IL2. Thereafter, a part that is exposed from the resist R2 of the insulating layer IL2 is removed by etching using the resist R2 as a mask. This forms the contact holes CH22 and CH32 in the insulating layer IL2 as shown in FIG. 14. The contact hole CH21 formed in the insulating layer IL1 and the contact hole CH22 formed in the insulating layer IL2 constitute the contact hole CH2. Further, the etching makes the insulating layer IL1 partially exposed from the insulating layer IL2. Thereafter, the lower electrode LE2 overlapping the contact hole CH2 is formed in the insulating layer IL2, as shown in FIG. 15. The lower electrode LE2 contacts the conductive layer CL through the contact hole CH2.

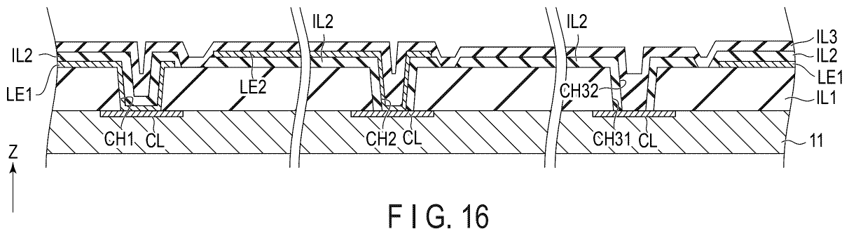

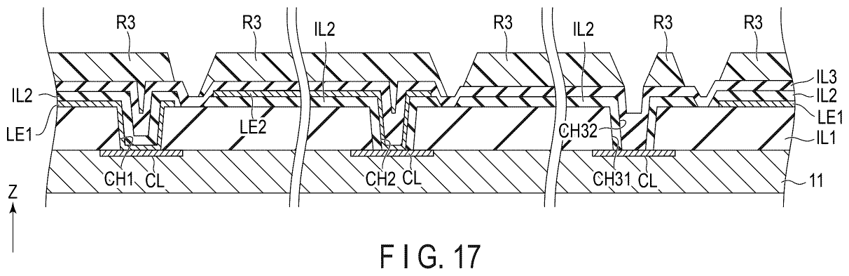

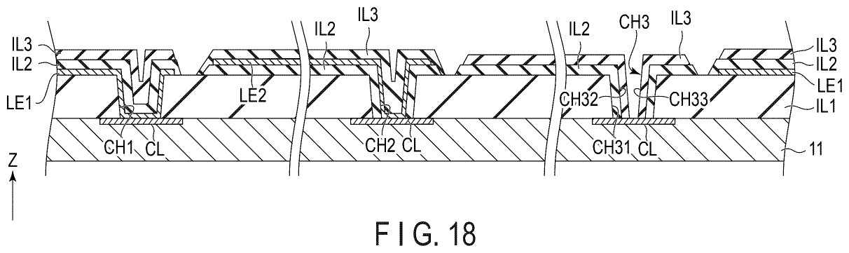

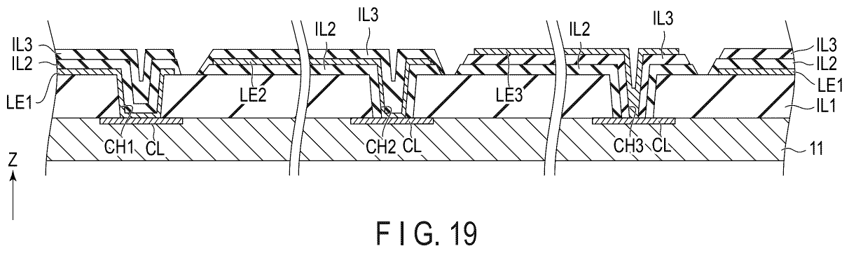

Thereafter, the insulating layer IL3 is formed on the insulating layer IL2 and the lower electrode LE2, as shown in FIG. 16. Thereafter, a resist R3 is provided on the insulating layer IL3, as shown in FIG. 17. The resist R3 covers a part of the insulating layer IL3. Thereafter, a part that is exposed from the resist R3 of the insulating layer IL3 is removed by etching using the resist R3 as a mask. This forms the contact hole CH33 in the insulating layer IL3, as shown in FIG. 18. The contact hole CH31 formed in the insulating layer IL1, the contact hole CH32 formed in the insulating layer IL2, and the contact hole CH33 formed in the insulating layer IL3 constitute the contact hole CH3. Further, the etching makes the insulating layer IL1 partially exposed from the insulating layer IL3. Thereafter, the lower electrode LE3 overlapping the contact hole CH3 is formed in the insulating layer IL3, as shown in FIG. 19. The lower electrode LE3 contacts the conductive layer CL through the contact hole CH3.

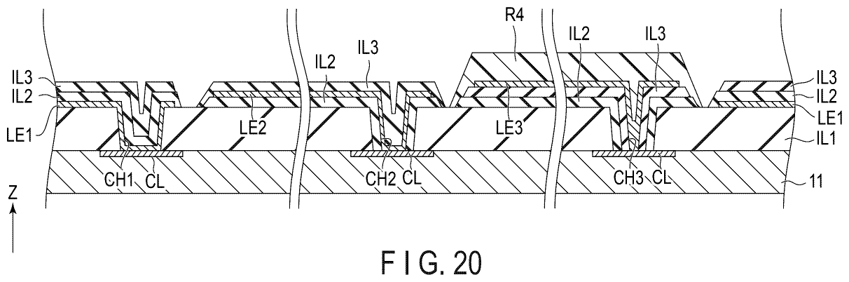

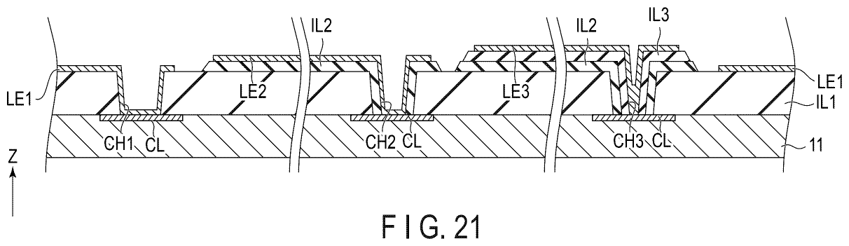

Thereafter, the resist R4 covering the lower electrode LE3 is provided, as shown in FIG. 20. Thereafter, the insulating layers IL2 and IL3 located on the lower electrode LE1 and the insulating layer IL3 located on the lower electrode LE2 are removed by etching using the resist R4 as a mask. This makes the lower electrodes LE1 and LE2 exposed, as shown in FIG. 21.

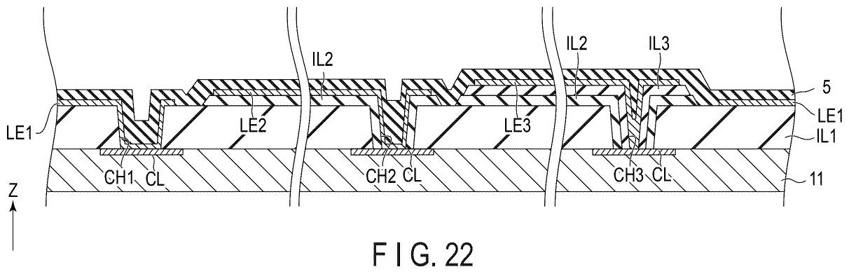

Subsequently, the rib layer 5 covering the lower electrodes LE1, LE2, and LE3 is formed, as shown in FIG. 22. The rib layer 5 covers end portions of the insulating layers IL2 and IL3. The rib layer 5 contacts the insulating layer IL1 in spaces among the lower electrodes LE1, LE2, and LE3.

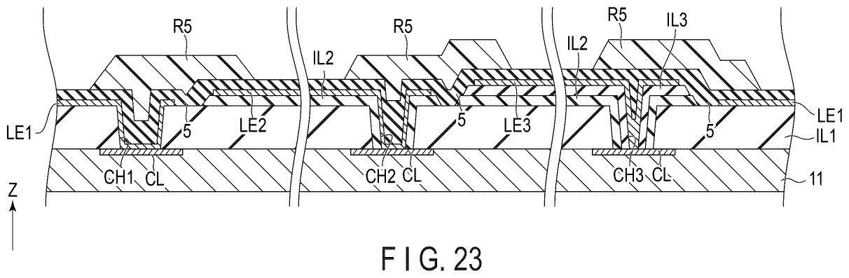

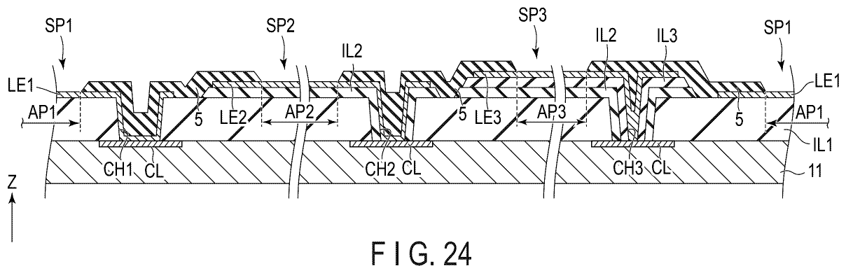

Thereafter, a resist R5 is formed on the rib layer 5, as shown in FIG. 23. The resist R5 covers a part of the rib layer 5. Thereafter, a part that is exposed from the resist R5 of the rib layer 5 is removed by etching using the resist R5 as a mask. This forms the pixel aperture AP1 overlapping the lower electrode LE1, the pixel aperture AP2 overlapping the lower electrode LE2, and the pixel aperture AP3 overlapping the lower electrode LE3 in the rib layer 5, as shown in FIG. 24.

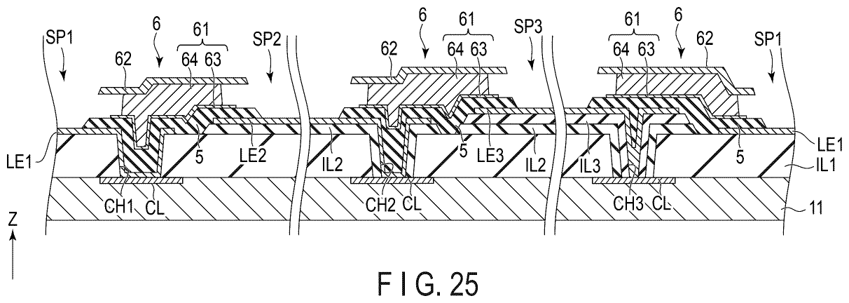

Subsequently, the partition 6 is formed on the rib layer 5, as shown in FIG. 25. In the step of forming the partition 6, the conductive lower portion 61 is formed on the rib layer 5. The lower portion 61 includes the bottom layer 63 formed on the rib layer 5 and the stem layer 64 formed on the bottom layer 63. Subsequently, the upper portion 62 protruding from the side surfaces of the lower portion 61 is formed on the stem layer 64 (the lower portion 61). The process of forming the partition 6 is not limited to the above process. For example, a layer to be processed into the bottom layer 63, a layer to be processed into the stem layer 64, and a layer to be processed into the upper portion 62 may be stacked on the rib layer 5 in this order. Then, the upper portion 62, the stem layer 64, and the bottom layer 63 may be formed in this order by etching. In the present embodiment, the partition 6 is formed after forming the pixel apertures AP1, AP2, and AP3, but may be formed before forming the pixel apertures AP1, AP2, and AP3.

After forming the rib layer 5 and the partition 6, processes of forming the display elements DE1, DE2, and DE3 are performed. The present embodiment assumes a case where the display element DE1 is formed first, the display element DE2 is formed next, and the display element DE3 is formed last. The formation order of the display elements DE1, DE2, and DE3 is not limited to this example.

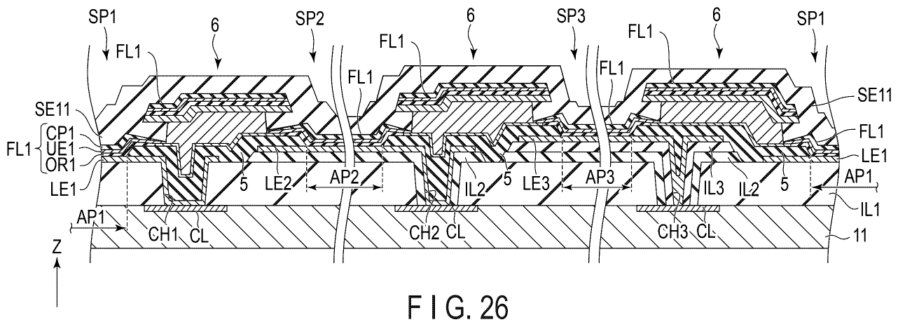

In forming the display element DE1, the stacked film FL1 and the sealing layer SE11 are formed first, as shown in FIG. 26. The stacked film FL1 includes the organic layer OR1, the upper electrode UE1, and the cap layer CP1. The organic layer OR1 is formed on the lower electrode LE1 and covers the lower electrode LE1. The organic layer OR1 contacts the lower electrode LE1 through the pixel aperture AP1. The upper electrode UE1 is formed on the organic layer OR1 and covers the organic layer OR1. The cap layer CP1 is formed on the upper electrode UE1 and covers the upper electrode UE1. The sealing layer SE11 is formed on the cap layer CP1 and covers the cap layer CP1.

The organic layer OR1, the upper electrode UE1, and the cap layer CP1 are formed by vapor deposition. The sealing layer SE11 is formed by chemical vapor deposition (CVD). The partition 6 having an overhang shape divides the stacked film FL1 into a plurality of portions. The sealing layer SE11 continuously covers these portions, into which the stacked film FL1 has been divided, and the partition 6.

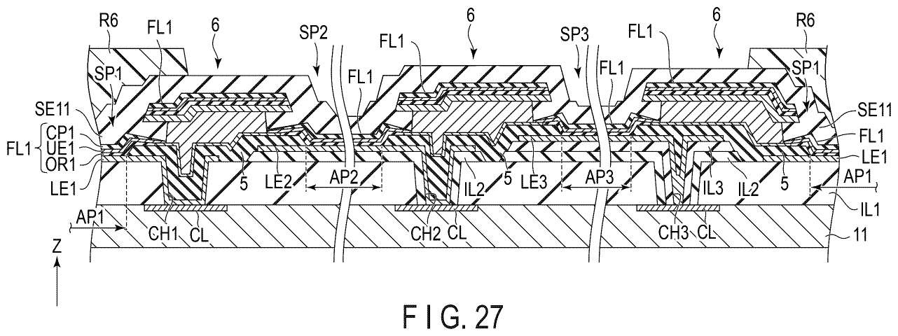

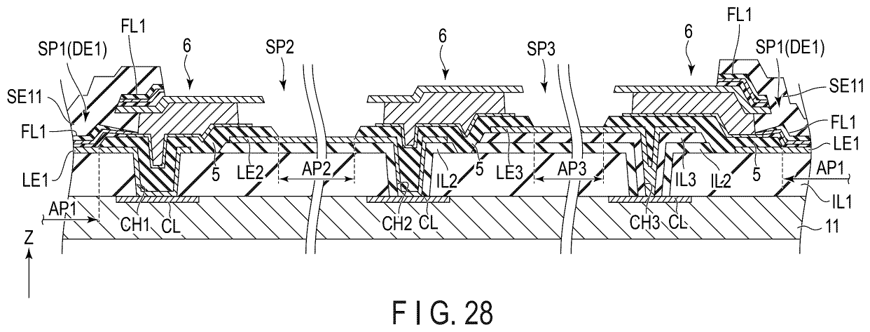

After forming the stacked film FL1 and the sealing layer SE11, a resist R6 is provided on the sealing layer SE11, as shown in FIG. 27. The resist R6 covers the subpixel SP1 and a part of the partition 6 around it. Subsequently, parts that are exposed from the resist R6 of the stacked film FL1 and sealing layer SE11 are removed by etching using the resist R2 as a mask. By this process, the display element DE1 is formed in the subpixel SP1, as shown in FIG. 28. For example, this etching includes wet etching and dry etching processes, which are performed in order on the sealing layer SE11, the cap layer CP1, the upper electrode UE1, and the organic layer OR1. After these etching processes, the resist R6 is removed.

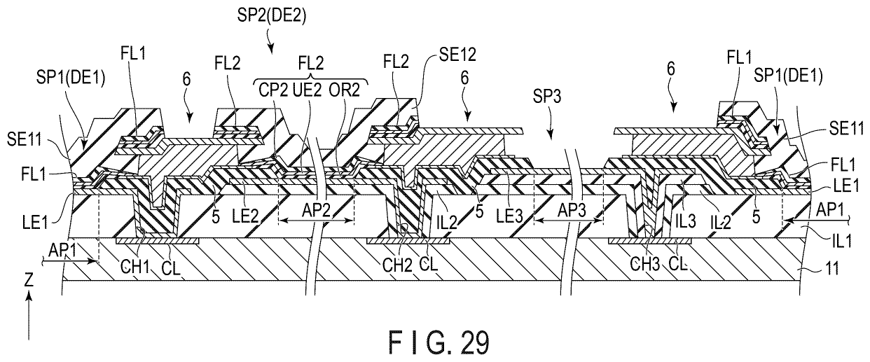

The display element DE2 is formed by a procedure similar to that of the display element DE1. That is, the stacked film FL2 and the sealing layer SE12 are formed in forming the display element DE2, as shown in FIG. 29. Here, the stacked film FL2 includes the organic layer OR2, the upper electrode UE2, and the cap layer CP2. The organic layer OR2 is formed on the lower electrode LE2 and covers the lower electrode LE2. The organic layer OR2 contacts the lower electrode LE2 through the pixel aperture AP2. The upper electrode UE2 is formed on the organic layer OR2 and covers the organic layer OR2. The cap layer CP2 is formed on the upper electrode UE2 and covers the upper electrode UE2. The sealing layer SE12 is formed on the cap layer CP2 and covers the cap layer CP2.

The organic layer OR2, the upper electrode UE2, and the cap layer CP2 are formed by vapor deposition. The sealing layer SE12 is formed by CVD.

The partition 6 having an overhang shape divides the stacked film FL2 into a plurality of portions. The sealing layer SE12 continuously covers these portions, into which the stacked film FL2 has been divided, and the partition 6.

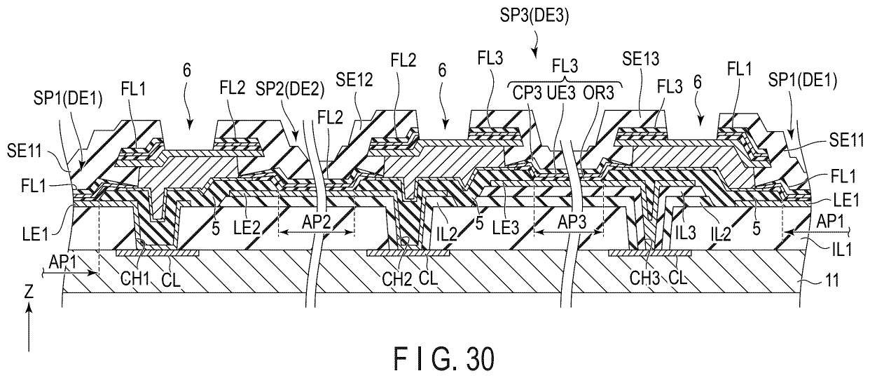

The display element DE3 is formed by procedures similar to the procedures of the display elements DE1 and DE2. That is, the stacked film FL3 and the sealing layer SE13 are formed in forming the display element DE3, as shown in FIG. 30. The stacked film FL3 includes the organic layer OR3, the upper electrode UE3, and the cap layer CP3. The organic layer OR3 is formed on the lower electrode LE3 and covers the lower electrode LE3. The organic layer OR3 contacts the lower electrode LE3 through the pixel aperture AP3. The upper electrode UE3 is formed on the organic layer OR3 and covers the organic layer OR3. The cap layer CP3 is formed on the upper electrode UE3 and covers the upper electrode UE3. The sealing layer SE13 is formed on the cap layer CP3 and covers the cap layer CP3.

The organic layer OR3, the upper electrode UE3, and the cap layer CP3 are formed by vapor deposition. The sealing layer SE13 is formed by CVD. The partition 6 having an overhang shape divides the stacked film FL3 into a plurality of portions. The sealing layer SE13 continuously covers these portions, into which the stacked film FL3 has been divided, and the partition 6.

After forming the display elements DE1, DE2, and DE3, the resin layer RS1, the sealing layer SE2, and the resin layer RS2 are formed in order, as shown in FIG. 5. The display device DSP is completed through these processes.

In the display device DSP of the present embodiment, the lower electrode LE1 is located on the insulating layer IL1, the lower electrode LE2 is located on the insulating layer IL2, and the lower electrode LE3 is located on the insulating layer IL3. In such a configuration, short-circuiting of each of the lower electrodes LE1, LE2, and LE3 can be suppressed even when distances among the lower electrodes LE1, LE2, and LE3 are narrow. As a result, the distances among the lower electrodes LE1, LE2, and LE3 are shorten. This can provide the display device DSP with the high aperture.

### Second Embodiment

Next, the second embodiment will be described. Except configurations described below, the second embodiment has the same configurations as the first embodiment.

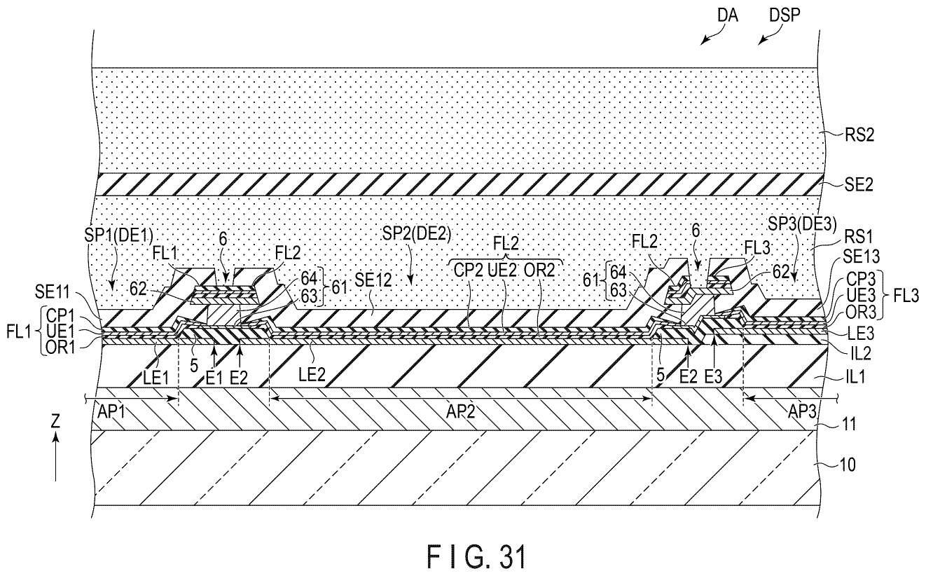

FIG. 31 is a schematic cross-sectional view of a display device DSP of the second embodiment. In the present embodiment, lower electrodes LE1 and LE2 are located on an insulating layer IL1, and a lower electrode LE3 is located on an insulating layer IL2.

In this configuration as well, the distance between the lower electrodes LE2 and LE3 and the distance between the lower electrodes LE1 and LE3 can be shorten. Thus, the same effects as those described above can be achieved.

The lower electrode LE1 may be located on the insulating layer IL1, and the lower electrodes LE2 and LE3 may be located on the insulating layer IL2. At least one of the lower electrodes LE1, LE2, and LE3 is located on the insulating layer IL1, and at least one of the lower electrodes LE1, LE2, and LE3 is located on the insulating layer IL2. Thus, this configuration can achieve the same effects as those described above.

### Third Embodiment

Next, the third embodiment will be described. The structures that are not particularly referred to are the same as those in each of the above embodiments.

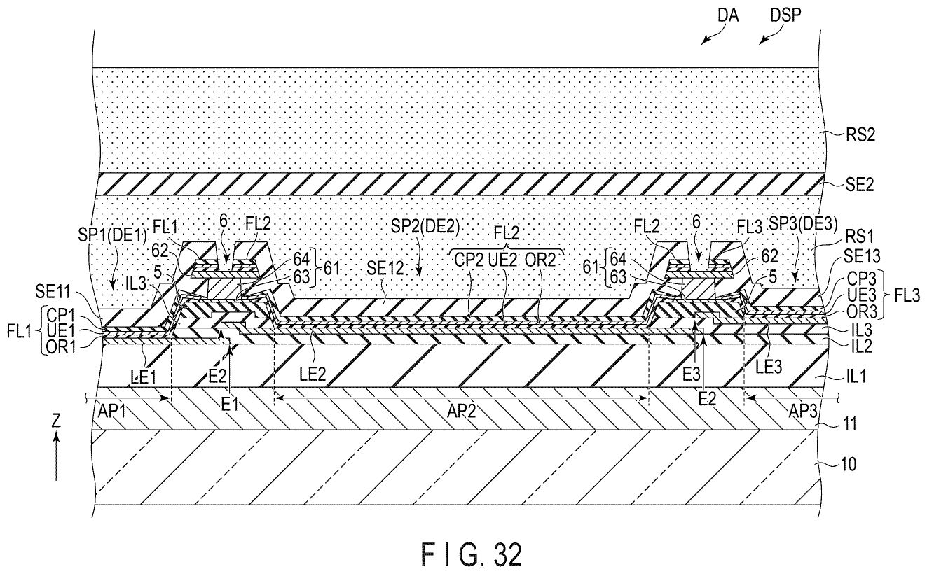

FIG. 32 is a schematic cross-sectional view showing a display device DSP of the third embodiment. In the present embodiment, an insulating layer IL2 directly covers a peripheral portion El of a lower electrode LE1, and an insulating layer IL3 directly covers a peripheral portion E2 of a lower electrode LE2. Further, a rib layer 5 is located on the insulating layer IL3 and directly covers a peripheral portion E3 of a lower electrode LE3. The peripheral portions E1, E2, and E3 overlap one another in plan view.

An example of a manufacturing method of the display device DSP of the third embodiment will be described next.

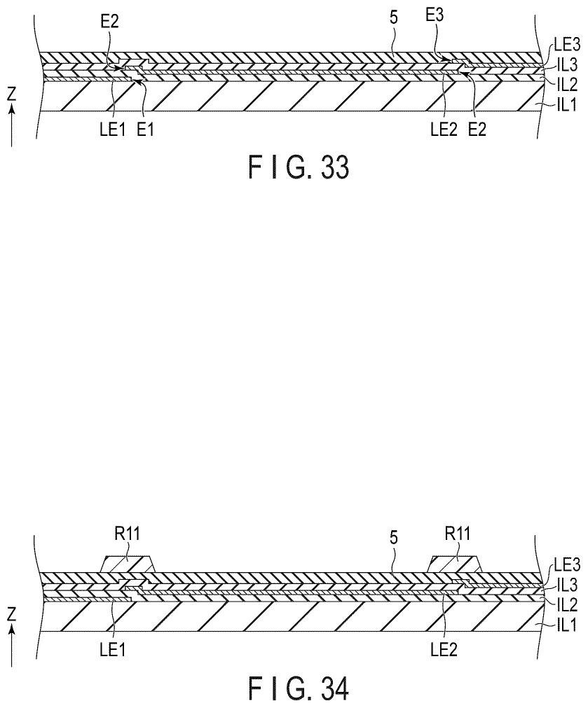

FIG. 33 to FIG. 35 are schematic cross-sectional views showing part of the manufacturing method of the display device DSP of the third embodiment. These figures omit illustration of the contact holes CH1, CH2, and CH3 shown in FIG. 2, and the substrate 10 and the circuit layer 11 shown in FIG. 32.

The insulating layer IL1 and the lower electrode LE1 are formed in the same processes as those described with reference to FIG. 8 to FIG. 11. After forming the lower electrode LE1, the insulating layer IL2 covering the lower electrode LE1 is formed on the insulating layer IL1 and the lower electrode LE1, as shown in FIG. 33. Thereafter, the lower electrode LE2 is formed on the insulating layer IL2. The peripheral portion E2 of the lower electrode LE2 overlaps the peripheral portion El of the lower electrode LE1 in the Z direction. Thereafter, the insulating layer IL3 covering the lower electrode LE2 is formed on the insulating layer IL2 and the lower electrode LE2. Thereafter, the lower electrode LE3 is formed on the insulating layer IL3. The peripheral portion E3 of the lower electrode LE3 overlaps the peripheral portion E2 of the lower electrode LE2 in the Z direction. Thought not illustrated, the peripheral portion E3 of the lower electrode LE3 overlaps the peripheral portion E1 of the lower electrode LE1 in the Z direction. Thereafter, the rib layer 5 covering the lower electrode LE3 is formed on the insulating layer IL3 and the lower electrode LE3.

Further, though not illustrated, contact holes CH22 and CH32 are formed in the insulating layer IL2 in the same processes as those described with reference to FIG. 13 and FIG. 14 after the processes of forming the insulating layer IL2. Further, though not illustrated, a contact hole CH33 is formed on the insulating layer IL3 in the same processes as those described with reference to FIG. 17 and FIG. 18 after the process of forming the insulating layer IL3.

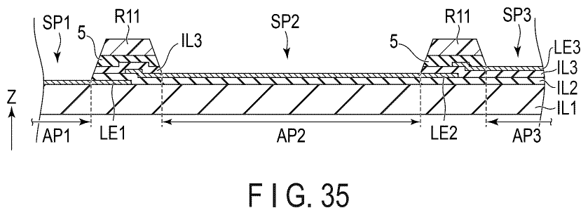

Thereafter, a resist R11 is formed on the rib layer 5, as shown in FIG. 34. The resist R11 covers a part of the rib layer 5. Thereafter, parts that are exposed from the resist R11 of the rib layer 5 and the insulating layers IL2 and IL3 are removed by etching using the resist R11 as a mask. Thus, pixel apertures AP1, AP2, and AP3 are formed, as shown in FIG. 35. Thereafter, the display device DSP is completed through the same processes as those described above.

In the present embodiment, the peripheral portions E1, E2, and E3 of the respective lower electrodes LE1, LE2, and LE3 overlap one another in plan view. This configuration allows each of the pixel apertures AP1, AP2, and AP3 to have the aperture ratio higher than those in the display devices DSP of the first embodiment and the second embodiment.

### Fourth Embodiment

Next, the fourth embodiment will be described. The structures that are not particularly referred to are the same as those in each of the above embodiments.

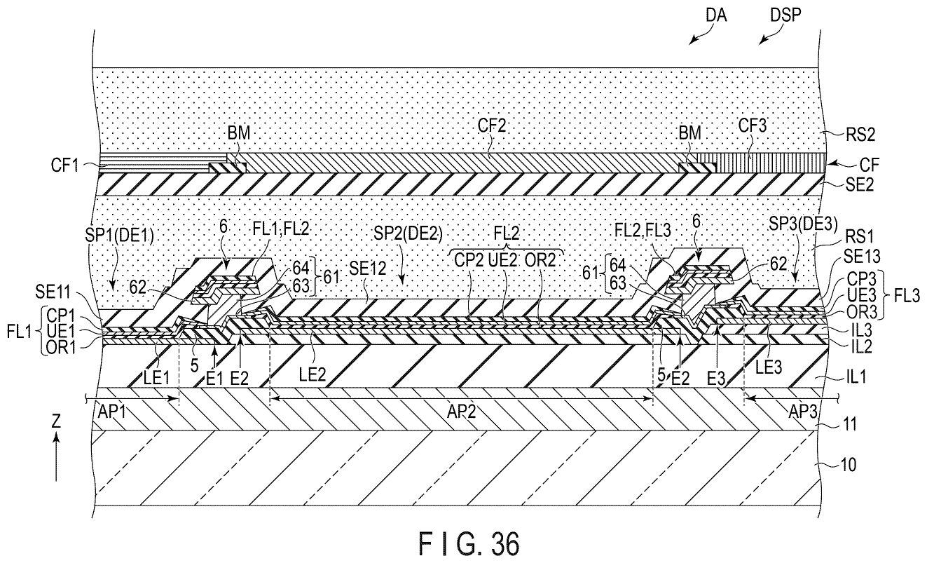

FIG. 36 is a schematic cross-sectional view of a display device DSP of the fourth embodiment. In the present embodiment, organic layers OR1, OR2, and OR3 are configured to emit light in white. Stacked films FL1, FL2, and FL3 cover the entire top surface of a partition 6 (the top surface of an upper portion 62).

The display device DSP further comprises a color filter layer CF. The color filter layer CF is located above lower electrodes LE1, LE2, and LE3 (display elements DE1, DE2, and DE3). In the example shown in FIG. 36, the color filter layer CF is located on a sealing layer SE2 and is covered with a resin layer RS2. The position of the color filter layer CF is not limited to this position.

The color filter layer CF includes color filters CF1, CF2, and CF3. For example, the color filter CF1 is formed of a resin material colored in red, the color filter CF2 is formed of a resin material colored in green, and the color filter CF3 is formed of a resin material colored in blue. The color filter CF1 is located directly above the lower electrode LE1 (the display element DE1). The color filter CF2 is located directly above the lower electrode LE2 (the display element DE2). The color filter CF3 is located directly above the lower electrode LE3 (the display element DE3).

A light-shielding layer BM is provided between the color filter layer CF and the sealing layer SE2. For example, the light-shielding layer BM is formed into a grating shape and overlaps the rib layer 5 and the partition 6 in plan view.

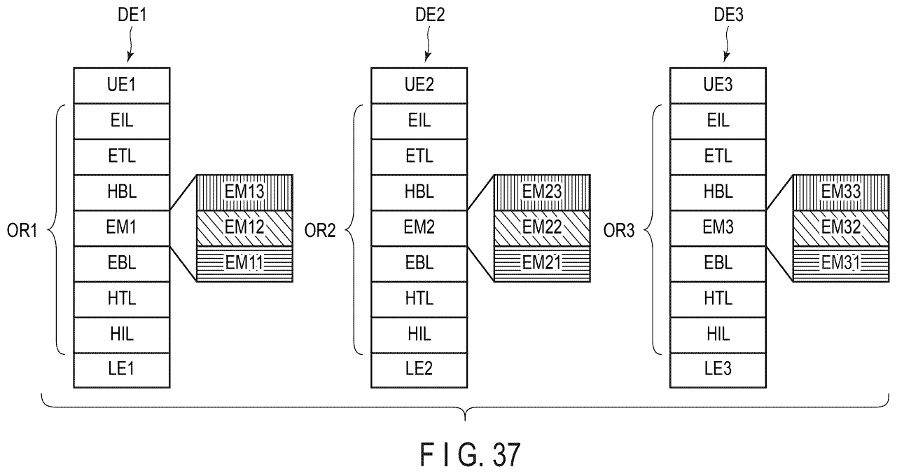

FIG. 37 is a view showing an example of structures applicable to the display elements DE1, DE2, and DE3 of the fourth embodiment. Other than the layer configuration of light emitting layers, EM1, EM2, and EM3, the display elements DE1, DE2, and DE3 that are shown in FIG. 37 are formed in the manner same as the display elements DE1, DE2, and DE3 that are shown in FIG. 4.

The light emitting layer EM1 included in the organic layer OR1 includes a light emitting layer EM11 emitting light in red (the first light emitting layer), a light emitting layer EM12 emitting light in green (the second light emitting layer), and a light emitting layer EM13 emitting light in blue (the third light emitting layer). The light emitting layers EM11, EM12, and EM13 are stacked. More specifically, the light emitting layer EM11 is located on an electron-blocking layer EBL, the light emitting layer EM12 is located on the light emitting layer EM11, and the light emitting layer EM13 is located on the light emitting layer EM12. The stack order of the light emitting layers EM11, EM12, and EM13 is not limited to this example. Further, the organic layer OR1 may include light emitting layers emitting light in colors different from the above colors.

The light emitting layer EM2 included in the organic layer OR2 includes a light emitting layer EM21 emitting light in red (the first light emitting layer), a light emitting layer EM22 emitting light in green (the second light emitting layer), and a light emitting layer EM23 emitting light in blue (the third light emitting layer). The light emitting layers EM21, EM22, and EM23 are stacked. More specifically, the light emitting layer EM21 is located on the electron-blocking layer EBL, the light emitting layer EM22 is located on the light emitting layer EM21, and the light emitting layer EM23 is located on the light emitting layer EM22. The stack order of the light emitting layers EM21,

EM22, and EM23 is not limited to this example. Further, the organic layer OR2 may include light emitting layers emitting light in colors different from the above colors.

The light emitting layer EM3 included in the organic layer OR3 includes a light emitting layer EM31 emitting light in red (the first light emitting layer), a light emitting layer EM32 emitting light in green (the second light emitting layer), and the light emitting layer EM33 emitting light in blue (the third light emitting layer). The light emitting layers EM31, EM32, and EM33 are stacked. More specifically, the light emitting layer EM31 is located on the electron-blocking layer EBL, the light emitting layer EM32 is located on the light emitting layer EM31, and the light emitting layer EM33 is located on the light emitting layer EM32. The stack order of the light emitting layers EM31, EM32, and EM33 is not limited to this example. Further, the organic layer OR3 may include light emitting layers emitting light in colors different from the above colors.

Thus, this configuration can achieve the same effects as those described above.

### Fifth Embodiment

Next, the fifth embodiment will be described. The structures that are not particularly referred to are the same as those in each of the above embodiments.

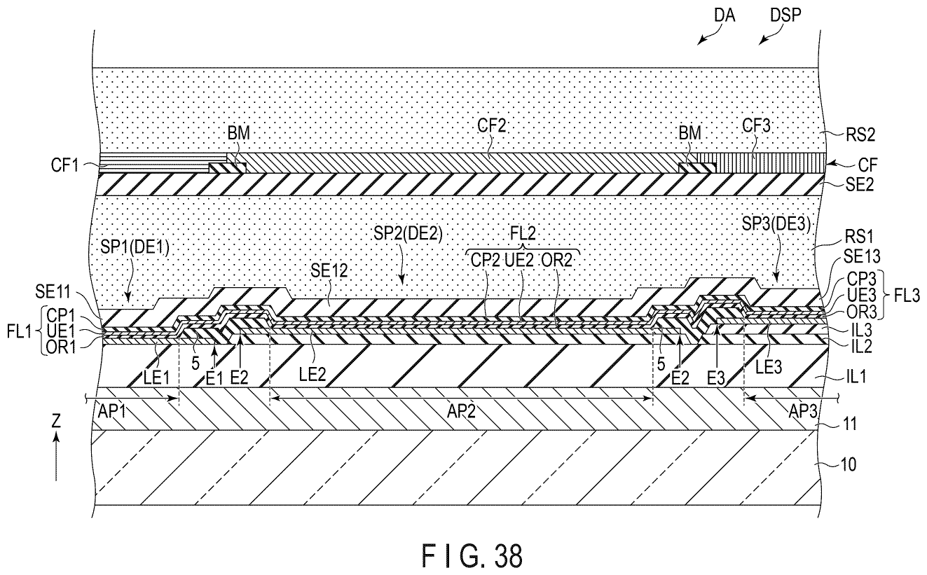

FIG. 38 is a schematic cross-sectional view of a display device DSP of the fifth embodiment. Unlike the other embodiments, the display device DSP of the fifth embodiment does not comprise the partition 6. Further, organic layers OR1, OR2, and OR3 are an integrally-formed common layer. Similarly, upper electrodes UE1, UE2, and UE3 are an integrally-formed common electrode, cap layers CP1, CP2, and CP3 are an integrally-formed common layer, and sealing layers SE11, SE12, and SE13 are an integrally-formed common layer. In the example of FIG. 38, display elements DE1, DE2, and DE3 are composed of the equivalent layers of the display elements DE1, DE2, and DE3 that are shown in FIG. 37. That is, the organic layers OR1, OR2, and OR3 are configured to emit light in white.

An example of a manufacturing method of the display device DSP of the fifth embodiment will be described next.

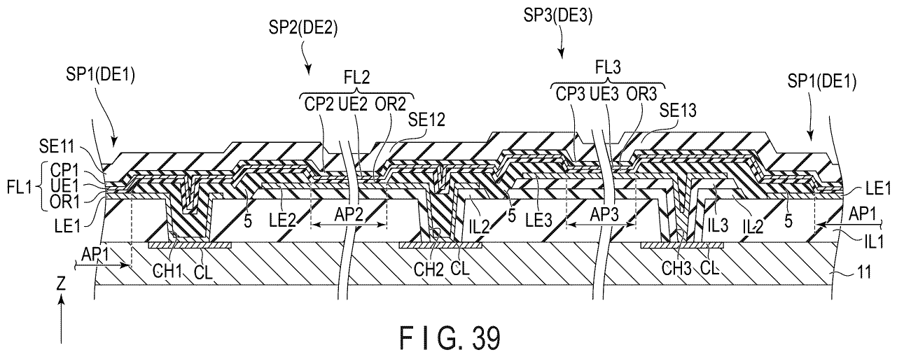

FIG. 39 is a schematic cross-sectional view showing part of the manufacturing method of the display device DSP of the fifth embodiment.

The processes conducted until forming the rib layer 5 are the same as those described with reference to FIG. 8 to FIG. 24. After forming the rib layer 5, the organic layers OR1, OR2, and OR3 are integrally formed on lower electrodes LE1, LE2, and LE3, as shown in FIG. 39. The organic layers OR1, OR2, and OR3 respectively cover the lower electrodes LE1, LE2, and LE3 through respective pixel apertures AP1, AP2, and AP3.

Thereafter, the upper electrodes UE1, UE2, and UE3 are integrally formed on the organic layers OR1, OR2, and OR3. Thereafter, the cap layers CP1, CP2, and CP3 are formed on the upper electrodes UE1, UE2, and UE3. Thereafter, the cap layers CP1, CP2, and CP3 are formed on the sealing layers SE11, SE12, and SE13. Thereafter, the display device DSP is completed through the same processes as those described above.

Thus, this configuration can achieve the same effects as those described above.

All of the display devices and the manufacturing methods of the display devices that can be implemented by a person of ordinary skill in the art through arbitrary design changes to the display device and the manufacturing method of the display device described above as the embodiments of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a first insulating layer;
a first lower electrode located on the first insulating layer and having a first peripheral portion;
a second insulating layer located on the first insulating layer;
a second lower electrode located on the second insulating layer and having a second peripheral portion;
a third insulating layer located on the second insulating layer;
a third lower electrode located on the third insulating layer and having a third peripheral portion;
a rib layer overlapping the first peripheral portion, the second peripheral portion, and the third peripheral portion and formed of inorganic material;
a first organic layer located on the first lower electrode;
a second organic layer located on the second lower electrode;
a third organic layer located on the third lower electrode;
a first upper electrode located on the first organic layer;
a second upper electrode located on the second organic layer; and
a third upper electrode located on the third organic layer.

2. The display device of claim 1, wherein
the rib layer directly covers the first peripheral portion, the second peripheral portion, and the third peripheral portion.

3. The display device of claim 2, wherein
the rib layer contacts the first insulating layer.

4. The display device of claim 1, wherein
the second insulating layer directly covers the first peripheral portion,
the third insulating layer directly covers the second peripheral portion, and
the rib layer is located on the third insulating layer and directly covers the third peripheral portion.

5. The display device of claim 1, wherein
at least two of the first peripheral portion, the second peripheral portion, and the third peripheral portion overlap one another in plan view.

6. The display device of claim 1, wherein
the first peripheral portion, the second peripheral portion, and the third peripheral portion overlap one another in plan view.

7. The display device of claim 1, further comprising:
a partition that includes a conductive lower portion provided on the rib layer and an upper portion protruding from a side surface of the lower portion and provided on the lower portion, wherein
the partition surrounds each of the first organic layer, the second organic layer, the third organic layer, the first upper electrode, the second upper electrode, and the third upper electrode, and
the first upper electrode, the second upper electrode, and the third upper electrode contact the lower portion.

8. The display device of claim 7, wherein
the first peripheral portion, the second peripheral portion, and the third peripheral portion are located directly below the partition.

9. The display device of claim 7, wherein
the first organic layer, the second organic layer, and the third organic layer are configured to emit light in colors different from one another.

10. The display device of claim 1, wherein
the first organic layer, the second organic layer, and the third organic layer are an integrally-formed common layer, and
the first upper electrode, the second upper electrode, and the third upper electrode are an integrally-formed common electrode.

11. The display device of claim 7, wherein
the first organic layer, the second organic layer, and the third organic layer are configured to emit light in white.

12. The display device of claim 11, wherein
each of the first organic layer, the second organic layer, and the third organic layer includes:
a first light emitting layer emitting light in red;
a second light emitting layer emitting light in green; and
a third light emitting layer emitting light in blue, and
the first light emitting layer, the second light emitting layer, and the third light emitting layer are stacked.

13. The display device of claim 1, further comprising:
a color filter layer located above the first lower electrode, the second lower electrode, and the third lower electrode.

14. The display device of claim 1, wherein
the second insulating layer and the third insulating layer are formed of inorganic material.

15. The display device of claim 1, wherein
the first insulating layer includes a first contact hole overlapping the first lower electrode, a second contact hole overlapping the second lower electrode, and a third contact hole overlapping the third lower electrode,
the second insulating layer includes a fourth contact hole overlapping the second contact hole and a fifth contact hole overlapping the third contact hole, and
the third insulating layer includes a sixth contact hole overlapping the fifth contact hole.

16. A manufacturing method of a display device, the method comprising:
forming a first insulating layer;
forming a first lower electrode on the first insulating layer;
forming a second insulating layer on the first insulating layer;
forming a second lower electrode on the second insulating layer;
forming a third insulating layer on the second insulating layer;
forming a third lower electrode on the third insulating layer;
forming a rib layer overlapping a first peripheral portion of the first lower electrode, a second peripheral portion of the second lower electrode, and a third peripheral portion of the third lower electrode; and
forming a first organic layer and a first upper electrode that overlap the first lower electrode, a second organic layer and a second upper electrode that overlap the second lower electrode, and a third organic layer and a third upper electrode that overlap the third lower electrode.

17. The manufacturing method of claim 16, further comprising
forming a partition on the rib layer after forming the rib layer, and
forming the partition includes:
forming a conductive lower portion on the rib layer; and
forming an upper portion protruding from a side surface of the lower portion on the lower portion.

18. The manufacturing method of claim 17, wherein
forming the first organic layer, the first upper electrode, the second organic layer, the second upper electrode, the third organic layer, and the third upper electrode includes:
forming the first organic layer on the first lower electrode;
forming the first upper electrode on the first organic layer;
forming the second organic layer on the second lower electrode;
forming the second upper electrode on the second organic layer;
forming the third organic layer on the third lower electrode; and
forming the third upper electrode on the third organic layer.

19. The manufacturing method of claim 18, further comprising,
in an interval between forming the first upper electrode and forming the second organic layer,
forming a cap layer on the first upper electrode, and
forming a sealing layer on the cap layer.

20. The manufacturing method of claim 16, wherein
forming the first organic layer, the first upper electrode, the second organic layer, the second upper electrode, the third organic layer, and the third upper electrode includes:
integrally-forming the first organic layer, the second organic layer, and the third organic layer on the first lower electrode, the second lower electrode, and the third lower electrode, and
integrally-forming the first upper electrode, the second upper electrode, and the third upper electrode on the first organic layer, the second organic layer, and the third organic layer.
